(19) United States
(12) Patent Application Publication
(10) Pub. No.: US 2004/0231591 A1
(43) Pub. Date: Nov. 25, 2004

(54) Method for connecting materials by means of an atmospheric plasma

(76) Inventors: Sven Jacobsen, Fallingbostel (DE); Christian Kuckertz, Olpe (DE); Rainer Brandt, Dushorn (DE)

Correspondence Address: NORRIS, MCLAUGHLIN & MARCUS, P.A., 875 THIRD AVE, 18TH FLOOR, NEW YORK, NY, 10022, US

(21) Appl. No.: 10/489,907

(22) PCT Filed: Sep. 17, 2002
(86) PCT No.: PCT/EP02/10430

(30) Foreign Application Priority Data
Sep. 19, 2001 (DE) 101 46 295.6

(51) Int. Cl. C23C 16/00

(52) U.S. Cl. 118/718

(57) ABSTRACT

Method for producing a multi-layered film web by joining together at least film webs and/or at least one film web and at least one coating material, wherein that surface of at least one film web which is brought into contact with another film web or with a coating material is treated with an indirect atmospheric plasmatron, with the optional addition of a working gas to the plasma generated by the plasmatron.

The present invention relates to a method for the production of a multi-layered film web by connecting at least two film webs and/or at least one film web and at least one coating material whereby at least one film web and/or at least one coating material is treated on the jointing side with an indirect atmospheric plasmatron and a working gas may be added to the plasmatron.

Multi-layered films are currently used in many fields. These multi-layered films are produced using the methods lamination, layering, coating or the so-called sandwiching of at least two film webs and/or polymer materials whereby a multi-layered film is produced from the individual films or coating materials with the aid of an adhesive, primer and/or adhesion agent.

In addition, according to the prior art it is also possible to produce two film webs by changing the surface of one of the two bonded partners. For example, a method is known from DE OS 198 02 662 in which by means of corona treatment of one polymer surface two film webs are joined together without the-use of an adhesive. Two film webs may also be joined together using an atmospheric plasma. This method is disclosed, for example, in DE OS 198 10 680 in which the film is treated with an atmospheric plasma on the jointing side. In the atmospheric plasma method, a defined gas atmosphere, the plasma gas, is created by an electrical discharge in a plasma torch whose electrodes it flows around. The plasma gas is activated by this discharge and transported by a constant gas flow to the surface of the film whereby the electrical discharge does not come into contact with the surface of the film. According to the prior art, however, this method may only be used to join polyethylene (PE) in a particularly advantageous way with other films. With other material combinations, the achievable bond strengths are generally not comparable to those of layering or lamination.

Therefore, the object was to provide a method for the production of multi-layered film webs using atmospheric plasma with which virtually any material combination of films or films and coating materials may be combined with each other and with which bond strengths comparable to those of layering or lamination may be achieved.

This object is achieved by a method for the production of a multi-layered film web by connecting at least two film webs and/or at least one film web and at least one coating material whereby at least one film web and/or at least one coating material is treated on the jointing side with a preferably indirect atmospheric plasmatron and a working gas may be added to the plasmatron whereby the working gas is matched to the materials to be connected in such a way that they are chemically and/or physically compatible with each other.

Surprisingly, the adaptation of the working gas to the material surfaces to be joined enables virtually any material combination to be joined without using adhesion agents, primers or adhesives in such a way that a bond strength is created between the materials which is comparable to the bond strength values commonly found with lamination or layering or even superior to these. In many cases, the bond strength achieved is of an order of magnitude that could be described as inseparable as far as material joining is concerned.

For the purposes of the invention, chemically and/or physically compatible means that, depending on the choice of working gas, after the plasma treatment, bond strengths of at least 1 N/15 mm, preferably at least 2 N/15 mm, measured according to DIN 53357, Method B, are achieved.

According to the invention, the working gas is added to a plasmatron and guided along a direct current arc burning between two electrodes, preferably guided through vertically. This causes the working gas to be activated and/or split into molecular fragments. Molecular fragments are preferably ions, electrons and/or radicals. The working gas treated in this way then reaches the surface of the film web to be treated and/or the surface of the coating material.

According to the invention, the working gas comprises at least one reactive gas, at least one reactive aerosol, at least one inert gas or at least one inert aerosol. Preferably, the working gas is an optional mixture of at least two of these components. Also preferably, the working gas is a mixture of at least one reactive gas or at least one reactive aerosol and at least one inert gas or one inert aerosol.

According to the invention, the working gas is matched to the surfaces to be connected in such a way that at least one is modified so that the surfaces are chemically and/or physically compatible with each other. Preferably, at least one surface is treated with the plasmatron in such a way that groups are formed there which have a particular affinity with the second surface which is to be connected to the first. Particularly preferably, however, the working gas is matched to the material combination to be connected even if only one of the two film surfaces is treated with the plasmatron. If one film web has carboxyl groups on the surface, the surface of the other film web is preferably treated with the plasmatron in such a way that it also has carboxyl or OH groups.

Preferably, the reactive gases and/or aerosols are oxidative, reductive, crosslinking and/or graftable gases and/or aerosols which result in reactions corresponding to their designation on the surface in question.

The gases used may hereby preferably be used in optional mixtures of each other depending upon the materials to be connected. Preferably, mixtures of reactive and inert working gases should also be used whereby the reactive gases preferably account for a share of 5% to 95% relative to the total mixture.

Preferably used as oxidative gases and/or aerosols are oxygen-containing gases and/or aerosols such as oxygen (O₂), carbon dioxides (CO₂), carbon monoxide (CO), ozone (O₃), hydrogen peroxide gas (H₂O₂), water vapour (H₂O), vaporised methanol (CH₃ OH), nitrogen-containing gases and/or aerosols such as nitrous gases (NOₓ), dinitrogen oxide (N₂O), nitrogen (N₂), ammonia (NH₃), hydrazine (H₂N₄), sulphur-containing gases and/or aerosols such as sulphur dioxide (SO₂), sulphur trioxide (SO₃), fluorine-containing gases and/or aerosols such as tetrafluorocarbon (CF₄), sulphur hexafluoride (SF₆), xenon difluoride (XeF₂), nitrogen trifluoride (NF₃), boron trifluoride (BF₃), silicon tetrafluoride (SiF₄), hydrogen (H₂) or mixtures of at least two of these gases and/or aerosols.

Preferably used as reductive gases and/or aerosols are H₂S, SO₂, aldehydes or inorganic sulphur compounds.

The inert gases are preferably noble gases, argon (Ar) is preferred.

Preferably used as crosslinkable gases and/or aerosols are at least monosaturated hydrocarbons such as, for example, α-olefins, such as ethylene, propylene, butene, acetylene or butadiene, saturated hydrocarbons with the general composition CₙH₂ₙ₊₂, such as methane, ethane, propane, butane, pentane, iso-propane, iso-butane, vinyl compounds such as vinyl acetate, unsaturated carboxylic acids and their esters such as acrylic acid, methacrylic acid, alkyl (meth)acrylates such as ethyl methacrylate, silanes with the general formula SiₙH₂ₙ₊₂ halogenated silicon chlorides such as SiCl₄, SiCl₃H, SiCl₂H₂, SiClH₃, alkoxy silanes such as tetraethoxysilane, hexamethyldisilazane, hexamethyldisiloxane.

Preferably used as graftable gases and/or aerosols are maleic anhydride, acrylic acid compounds, vinyl compounds, carbon dioxide (CO₂).

However, a person skilled in the art will recognise that the action of the gas in question is determined by the film to be treated. For example, the same gas may have an oxidative effect with one film and a reductive effect with another film. The same applies to grafting and crosslinking gases.

To combine a polyolefin film with a metallised or printed polyethylene terephthalate film (PET film), the polyolefin film is preferably treated with a plasma based on an oxidative working gas, quite particularly preferably with O₂ and/or CO₂.

A person skilled in the art will understand that ‘polyolefins’ means both homopolymers and copolymers preferably based on polyethylene (high density polyethylene, low density polyethylene, linear low density polyethylene); metallocene-catalysed types; also preferably based on ethylene propylene copolymers, ethylene-octene copolymers, isomers, ethylene-vinyl acetate copolymers, ethylene methyl acrylate copolymers.

To combine a polyolefin film, preferably polyethylene, with a PET film, the PET film is preferably treated with a plasma based on a reductive working gas, quite particularly preferably with H₂S and/or SO₂, aldhehydes, inorganic sulphur compounds.

To combine a polyolefin film with a polypropylene film (PP film) or a biaxially oriented polyamide film (PAB film), both films are preferably treated with a plasma based on an oxidative working gas, quite particularly preferably with O₂ and/or CO₂.

To combine a polyolefin film, preferably polyethylene, with a (PET film), the polyolefin film is preferably treated with a plasma based on a working gas mixture of argon and O₂ whereby the Ar/O₂ mixing ratio is preferably 1.2-0.6 particularly preferably 0.75-0.95. The PE film may be low density PE (LDPE) and/or linear low density PE (LLDPE).

To combine a polyolefin film, preferably polyethylene, with a metal coating, the polyolefin film is preferably treated with a plasma based on a working gas mixture of argon and O₂ whereby the Ar/O₂ mixing ratio is preferably 1.0-0.4 particularly preferably 0.8-0.6. The PE film may be low density PE (LDPE) and/or linear low density PE (LLDPE).

To combine a polyolefin film, preferably polyethylene, with a coloured layer, based on polyvinyl chloride, polyvinvyl butyrate and/or nitrocellulose, the polyolefin film is preferably treated with a plasma based on a working gas mixture of argon and O₂ whereby the Ar/O₂ mixing ratio is preferably 1.3-0.7 particularly preferably 1.0-0.9. The PE film may be low density PE (LDPE) and/or linear low density PE (LLDPE).

To combine a film made of PE/PP copolymers (PE/PP film) with a preferably bidirectionally oriented polyamide film (PA film), the PE/PP film is preferably treated with a plasma based on a working gas mixture of argon and O₂ whereby the Ar/O₂ mixing ratio is preferably 0.1-0.5 particularly preferably 0.2-0.4.

The working gas preferably has a constant volumetric flow rate and a constant composition. Also preferably, the volumetric flow rate and/or the composition are changed regularly or irregularly during the process of the production of the multi-layer film.

The procedure according to the invention may, for example, be performed with an indirect plasmatron such as is described in EP A 85 1 720 but other atmospheric plasma torches with which additional working gases may be added and are able to treat the entire surface may also be used for this. EP A 85 1 720 is hereby introduced as a reference and hence is part of the disclosure.

The torch preferably has two electrodes arranged coaxially with a large distance between them. Between these, a direct current arc bums which is preferably wall-stabilised by a cascaded arrangement of freely adjustable length. Blowing in a working gas preferably transversally to the arc axis causes a preferably laterally escaping preferably band-shaped plasma beam to emerge. The working gas hereby passes through the direct current arc and is activated therein or split into molecular fragments (ions, electrons, radicals). However, advantageously it does not come into contact with the electrodes which may be damaged in particular by reactive species. This torch, also known as a plasma wide-beam torch, is preferably also characterised by the fact that a magnetic field exerts a force on the arc which counteracts the force exerted on the arc by the plasma gas flow. The torch described here is only one example of an embodiment of the atmospheric plasma torch according to the method according to the invention. Other embodiments are conceivable in which it is also possible to introduce a plasma gas flowing round the electrode and a working gas.

Preferably used as a plasma gas to protect the electrodes is an inert gas.

Preferably, the indirect plasmatron will be installed directly before the laminator gap in a conventional laminating machine and applied selectively to the jointing side of one of the two materials to be joined. Alternatively, both jointing surfaces are treated preferably simultaneously preferably directly in the laminator gap. The decision as to whether one jointing surface or both jointing surfaces are to be advantageously treated is dependent upon the materials to be connected and the composition of the plasma gas and has to be decided anew in each individual case. Similar embodiments are possible in coating or sandwiching systems directly before the two materials are brought together whereby in a particularly advantageous way the melt web of the coating material is treated.

Treatment of at least one film surface is preferably performed over the whole area which means that the treatment of at least one surface provided for joining is performed homogeneously on the entire area available. However, partial-area embodiments are also conceivable in which strips, areas or patterns are created on the surface to be treated. Also preferable is different treatment over the whole area created by the spatially different use of different working gases in different areas.

The method may be applied to any plastic films and plastic coating materials. The type of plastic is irrelevant at first. The only important factor is that the working gas is matched to the materials to be connected. In addition, however, in particular also metal films, preferably with a thickness of less than 100 μm may be connected to any plastic films or plastic coating materials. Here, once again, the type of material is immaterial. Particularly preferred, however, are aluminium films preferably with a thickness of between 4 μm and 30 μm.

In another preferred embodiment, at least one of the two films to be connected is metallised on at least one side in particular on the jointing side or provided with a metal or silicone oxide layer. These layers are preferably between 100 and 500 A thick.

In another preferred embodiment, one of the films to be connected is printed on at least one side. Particularly preferably, the jointing side is printed.

In another quite particularly preferred embodiment of the method according to the invention, one of the materials to be joined, either one of the films or one of the coating materials, is a sealable material preferably made of polyolefin or homopolymers or copolymers or amorphous polyethylene terephthalate.

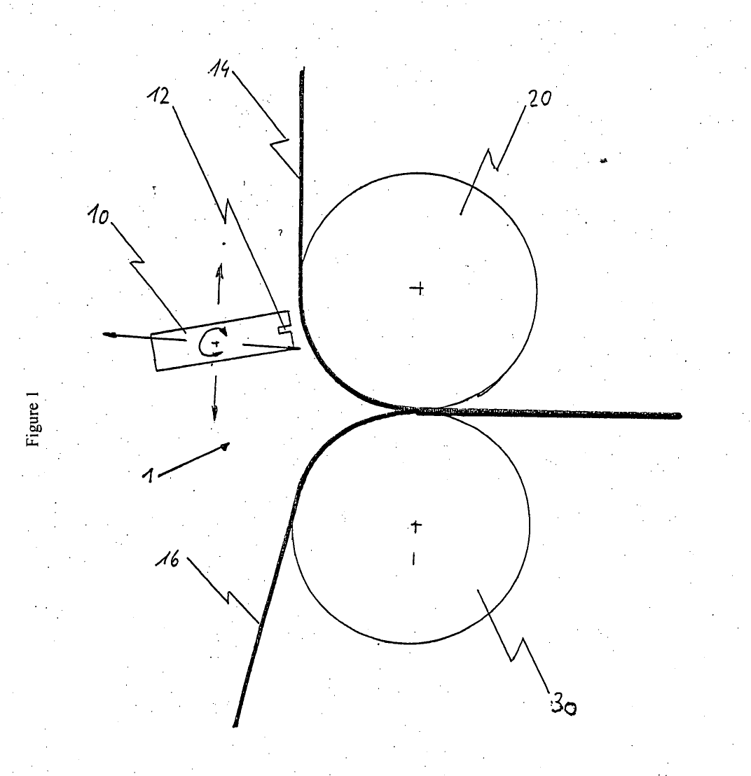

The following explains the invention with reference to FIG. 1 and examples 1-9. These explanations are by way of example only and do not restrict the general concept of the invention.

FIG. 1 shows an example of the construction of a system with which the method according to the invention may be performed. The treatment of the surface of the film is performed directly in front of the laminator gap. The plasma torch 10 is arranged so it may be moved horizontally and vertically and also mounted rotatably as indicated by the arrows. The plasma torch may be positioned at any point in front of the laminator gap between the laminating rolls 20, 30 so that the plasma gas emerging from the plasma gap 12 acts on one of the two surfaces or optionally on both surfaces simultaneously. The first film 14 rotates around the laminating roll 20 and the lower film 16 correspondingly around the laminating roll 30. The laminating rolls may both be cooled or heated.

In principle, all known and conceivable methods for layering, coating, lamination and for sandwiching which may be subsequently be fitted with suitable plasma units are possible.

### EXAMPLE 1

Two different materials are brought together in a commercial laminating machine. For this, the laminating machine has a working width of 600 mm and is provided with a plasma torch attached directly before the laminator gap whereby the spatial arrangement of said torch enables optionally either one of the two films or both film surfaces to be treated.

As the first film, a 12 μm thick polyethylene terephthalate film is introduced to the laminator gap. This is not treated by the plasma. As the second film, a 50 μm thick polyethylene film (50% LDPE, 50% LLDPE) is introduced and exposed over its entire width to plasma gas directly before the laminator gap. Hereby, the plasma gas exit gap is located 3 mm from the surface of the film. The laminating speed is 20 m/min. The working gas used is a mixture of 20 standard litres per minute (slm) of argon and 20 slm of oxygen. The cathode and anode are each rinsed with 2.5 slm of argon. After the laminator gap, the bond strengths are 2.3 N/15 mm to 2.7 N/15 mm. These values and the subsequent bond strengths are determined in accordance with DIN 53357, Method B.

### EXAMPLE 2

In this experiment, the conditions are similar to those in Example 1. However, the distance between the plasma exit nozzle and the surface of the film has been reduced to approximately 1.5 mm to achieve a better action of the reactive plasma components. The bond strength increases to >5 N/15 mm. The bond may be classed as inseparable since one of the bonded partners is destroyed.

### EXAMPLE 3

The experiments were performed on the laminating machine according to Example 1. As the first film, a 50 μm thick polyethylene terephthalate film is introduced to the laminator gap. This is not treated by the plasma. As the second film, a 50 μm thick polyethylene film (50% LDPE, 50% LLDPE) is introduced and exposed over its entire width to plasma gas directly before the laminator gap. Hereby, the plasma gas exit gap is located 2 mm from the surface of the film. The laminating speed is 10 m/min. The working gas used is a mixture of 20 standard litres per minute (slm) of argon and 24 slm of oxygen. The cathode and anode are each rinsed with 2.5 slm of argon. The bond strength is 5 N/15 mm and so the bond may be classed as inseparable.

### EXAMPLE 4

The experiments were performed on the laminating machine according to Example 1. As the first film, a 15 μm biaxially oriented polyamide is introduced to the laminator gap. As the second film, a 75 μm thick polyethylene/polypropylene copolymer film is introduced. The polyamide film is printed on the jointing side by intaglio printing with a PVC-based colour. The jointing side of the copolymer is hereby exposed to plasma gas shortly before the laminator gap. The laminating speed is 20 m/min. The working gas used is a mixture of 10 slm of argon 4.5 and 25 slm of CO₂. The cathode and anode are each rinsed with 2.5 slm of argon 5.0. The distance between the plasma exit opening and the surface of the film is 2 mm. After the laminator gap, the bond strengths are >3 N/15 mm. The separation picture reveals a division of the colour coating.

### EXAMPLE 5

The experiments were performed on the laminating machine according to Example 1. As the first film, a 60 μm thick polyethylene (LLDPE) is introduced to the laminator gap. The second film is a 12 μm thick PET film with a metal coating. The jointing side of the polyethylene film is exposed to plasma gas shortly before the laminator gap. The laminating speed is 10 m/min. The working gas used is a mixture of 20 slm of argon 4.5 and 28 slm of O₂. The cathode and anode are each rinsed with 2.5 slm of argon 5.0. The distance between the plasma exit opening and the surface of the film is 2 mm. After the laminator gap, the bond strengths are >3 N/15 mm whereby the metal coating is transferred to the PE film.

### EXAMPLE 6

The experiments were performed on the laminating machine according to Example 1. As the first film, a 60 μm thick polyethylene (LLDPE) is introduced to the laminator gap. The second film is a 12 μm thick PET film printed with a PVC-based colour. The jointing side of the polyethylene film is exposed to plasma gas shortly before the laminator gap. The laminating speed is 20 m/min. The working gas used is a mixture of 20 slm of argon 4.5 and 20 slm of O₂. The cathode and anode are each rinsed with 2.5 slm of argon 5.0. The distance between the plasma exit opening and the surface of the film is 2 mm. After the laminator gap, the bond strengths are >3 N/15 mm. The separation picture reveals a division of the colour coating.

### EXAMPLE 7

The experiments were performed on the laminating machine according to Example 1. As the first film, a 50 μm thick PE/PP copolymer film (polyethylene¹) is introduced to the laminator gap. As the second film, a 15 μm thick bidirectionally oriented polyamide film printed with a PVC-based colour is fed to the gap. The jointing side of the polyethylene film is exposed to plasma gas shortly before the laminator gap. The laminating speed is 15 m/min. The working gas used is a mixture of 10 slm of argon 4.5 and 30 slm of CO₂. The cathode and anode are each rinsed with 2.5 slm of argon 5.0. The distance between the plasma exit opening and the surface of the film is 3 mm. After the laminator gap, the bond strengths are >3 N/15 mm. The separation picture reveals a division of the colour coating. ¹Tr note: the word “polyethylene” has probably been included by mistake

### EXAMPLE 8

A film is coated with a coating material in a commercially available coating machine. Usually, in the case of incompatible materials, a primer or adhesion agent is applied to the film web before the connection. In this case, the melt web of the coating material is exposed to plasma working gas from an atmospheric wide-beam plasma torch as described above shortly before being joined to the film.

A 23 μm thick metallised polyester film is coated on the metallised side with a polyethylene copolymer at a rate of 30 m/min. The coating width is 300 mm. The melt web of the coating material is exposed spatially to plasma gas shortly before the two materials are joined. The plasma gas comprises 20 slm of argon 4.5 and 10 slm of oxygen. The anode and the cathode are each rinsed with 2.5 slm of argon 5.0. The distance between the plasma gas exit and the melt web is 10 mm. The coating thickness is 20 μm. The bond strength of the two bonded partners can subsequently be described as inseparable and is >6 N/mm.

### EXAMPLE 9

With the same plasma parameters as described in Example 8, a 25 μm thick co-extrudate comprising 10 μm polyamide 6/5 μm EVOH/10 μm polyamide 6 is coated with a 35 μm thick ionomer layer. Once again, the final bond can subsequently be characterised as inseparable with bond strengths >4 N/mm.

1. Method for the production of a multi-layered film web by connecting at least two film webs (14, 16) and/or at least one film web (16) and at least one coating material whereby at least one film web (16) and/or at least one coating material is treated on the side to be connected, with a plasmatron (10) and a working gas is added to the plasmatron, wherein the working gas comprises at least one reactive gas, at least one reactive aerosol, at least one inert gas or at least one inert aerosol and the bond strengths between the connected materials to be connected is at least 1 N/15 mm.

2. Method according to claim 1, wherein the working gas is a mixture of at least one reactive gas and/or at least one reactive aerosol and at least one inert gas.

3. Method according to claim 2, wherein the reactive gas and/or the reactive aerosol at least partially oxidizes said connecting side of said at least one film web and/or of said at least one coating material.

4. Method according to claim 2, wherein said at least one reactive gas and/or said at least one reactive aerosol at least partially crosslinks said connecting side of said at least one film web and/or of said at least one coating material.

5. Method according to claim 2, wherein the components of the reactive gas and/or the reactive aerosol are grafted onto said connecting side of said at least one film web and/or of said at least one coating material.

6. Method according to claim 1, wherein the content of reactive components in the working gas is 5-95 percent by weight.

7. Method according to claim 1, wherein said plasmatron is a plasmatron with an elongate plasma chamber, which in a cascaded construction comprises a plurality of neutrodes electrically insulated from each other, whereby the electrodes required to generate the plasma light gas are arranged coaxially to the longitudinal axis of the plasma chamber and the plasma beam exit opening runs parallel to the longitudinal axis of the plasma chamber.

8. Method according to claim 1, wherein said plasmatron is a plasmatron in which at least one neutrode is provided with a permanent magnet pair to influence the shape and position of the plasma light arc.

9. Method according to claim 1, wherein the treatment of said connecting side of said at least one film web and/or of said at least one coating material is performed over all or part of the surface thereof.

10. Method according to claim 1, wherein said at least one film web is a metal film with a thickness of less than 100 μm, or a plastic film.

11. Method according to claim 1, wherein said at least one of the film web connected is metallized or coated with metal and/or silicone oxide on at least one side.

12. Method according to claim 1, wherein at least one of the film webs to be connected is printed on at least one side.

13. Method according to claim 1, wherein one of the film webs to be connected is a sealable film which optionally comprises polyolefin homopolymers or polyolefin copolymers, amorphous polyethylene terephthalate or other sealable materials or wherein said at least one coating material is a sealable material component.

14. Method according to claim 1, wherein said plasmatron is an indirect atmospheric plasmatron.

15. Method according to claim 12, wherein said printing is on the connecting side.
